(19) United States
(12) Patent Application Publication
(10) Pub. No.: US 2024/0411222 A1
(43) Pub. Date: Dec. 12, 2024

(54) PELLICLE MEMBRANE FOR A LITHOGRAPHIC APPARATUS

(71) Applicant: ASML NETHERLANDS B.V., Veldhoven (NL)

(72) Inventors: Inci DONMEZ NOYAN, Eindhoven (NL); Ties Wouter VAN DER WOORD, Eindhoven (NL); Johan REININK, Uden (NL); Tim Willem Johan VAN DE GOOR, Breda (NL); Alexander Ludwig KLEIN, Eindhoven (NL); Zomer Silvester HOUWELING, Utrecht (NL); Paul Alexander VERMEULEN, Best (NL); Adrianus Johannes Maria GIESBERS, Vlijmen (NL); Johan Hendrik KLOOTWIJK, Eindhoven (NL); Lambertus Idris Johannes Catharina BERGERS, Veldhoven (NL)

(73) Assignee: ASML NETHERLANDS B.V., Veldhoven (NL)

(21) Appl. No.: 18/699,574

(22) PCT Filed: Oct. 7, 2022
(86) PCT No.: PCT/EP2022/077941

§ 371 Date: Apr. 8, 2024

(30) Foreign Application Priority Data
Oct. 22, 2021 (EP) 21204216.2

(51) Int. Cl. G03F 1/62; C04B 35/58

(52) U.S. Cl. CPC G03F 1/62; C04B 35/58; C04B 2235/3891; C04B 2235/428; C04B 2235/781

(57) ABSTRACT

A pellicle membrane includes a population of metal silicide crystals in a silicon-based matrix, wherein the pellicle membrane has an emissivity of 0.3 or more. Also a method of manufacturing a pellicle membrane, a pellicle assembly, a lithographic apparatus comprising such a pellicle membrane or pellicle assembly. Also the use of such a pellicle membrane, pellicle assembly, or lithographic apparatus in a lithographic apparatus or method.

### CROSS-REFERENCE TO RELATED APPLICATIONS

This application claims priority of EP application 21204216.2 which was filed on Oct. 22, 2021 and which is incorporated herein in its entirety by reference.

### FIELD

The present invention relates to a pellicle membrane for a lithographic apparatus, an assembly for a lithographic apparatus, methods of manufacturing a pellicle membrane, and a use of a pellicle membrane in a lithographic apparatus or method.

### BACKGROUND

A lithographic apparatus is a machine constructed to apply a desired pattern onto a substrate. A lithographic apparatus can be used, for example, in the manufacture of integrated circuits (ICs). A lithographic apparatus may for example project a pattern from a patterning device (e.g. a mask) onto a layer of radiation-sensitive material (resist) provided on a substrate.

The wavelength of radiation used by a lithographic apparatus to project a pattern onto a substrate determines the minimum size of features which can be formed on that substrate. A lithographic apparatus which uses EUV radiation, being electromagnetic radiation having a wavelength within the range 4-20 nm, may be used to form smaller features on a substrate than a conventional lithographic apparatus (which may for example use electromagnetic radiation with a wavelength of 193 nm).

A lithographic apparatus includes a patterning device (e.g. a mask or reticle). Radiation is provided through or reflected off the patterning device to form an image on a substrate. A membrane assembly, also referred to as a pellicle, may be provided to protect the patterning device from airborne particles and other forms of contamination. Contamination on the surface of the patterning device can cause manufacturing defects on the substrate.

Pellicles may also be provided for protecting optical components other than patterning devices. Pellicles may also be used to provide a passage for lithographic radiation between regions of the lithography apparatus which are sealed from one another. Pellicles may also be used as filters, such as spectral purity filters or as part of a dynamic gas lock of a lithographic apparatus.

A mask assembly may include the pellicle which protects a patterning device (e.g. a mask) from particle contamination. The pellicle may be supported by a pellicle frame, forming a pellicle assembly. The pellicle may be attached to the frame, for example, by gluing or otherwise attaching a pellicle border region to the frame. The frame may be permanently or releasably attached to a patterning device.

Due to the presence of the pellicle in the optical path of the EUV radiation beam, it is necessary for the pellicle to have high EUV transmissivity. A high EUV transmissivity allows a greater proportion of the incident radiation through the pellicle. In addition, reducing the amount of EUV radiation absorbed by the pellicle may decrease the operating temperature of the pellicle. Since transmissivity is at least partially dependent on the thickness of the pellicle, it is desirable to provide a pellicle which is as thin as possible whilst remaining reliably strong enough to withstand the sometimes hostile environment within a lithography apparatus.

It is therefore desirable to provide a pellicle which is able to withstand the harsh environment of a lithographic apparatus, in particular an EUV lithography apparatus. It is particularly desirable to provide a pellicle which is able to withstand higher powers than previously.

Whilst the present application generally refers to pellicles in the context of lithography apparatus, in particular EUV lithography apparatus, the invention is not limited to only pellicles and lithography apparatus and it is appreciated that the subject matter of the present invention may be used in any other suitable apparatus or circumstances.

For example, the methods of the present invention may equally be applied to spectral purity filters. Some EUV sources, such as those which generate EUV radiation using a plasma, do not only emit desired ‘in-band’ EUV radiation, but also undesirable (out-of-band) radiation. This out-of-band radiation is most notably in the deep UV (DUV) radiation range (100 to 400 nm). Moreover, in the case of some EUV sources, for example laser produced plasma EUV sources, the radiation from the laser, usually at 10.6 microns, presents a significant out-of-band radiation.

In a lithographic apparatus, spectral purity is desired for several reasons. One reason is that the resist is sensitive to out of-band wavelengths of radiation, and thus the image quality of patterns applied to the resist may be deteriorated if the resist is exposed to such out-of-band radiation. Furthermore, out-of-band radiation infrared radiation, for example the 10.6 micron radiation in some laser produced plasma sources, leads to unwanted and unnecessary heating of the patterning device, substrate, and optics within the lithographic apparatus. Such heating may lead to damage of these elements, degradation in their lifetime, and/or defects or distortions in patterns projected onto and applied to a resist-coated substrate.

A typical spectral purity filter may be formed, for example, from a silicon foundation structure (e.g. a silicon grid, or other member, provided with apertures) that is coated with a reflective metal, such as molybdenum. In use, a typical spectral purity filter might be subjected to a high heat load from, for example, incident infrared and EUV radiation. The heat load might result in the temperature of the spectral purity filter being above 800° C. Under the high head load, the coating can delaminate due to a difference in the coefficients of linear expansion between the reflective molybdenum coating and the underlying silicon support structure. Delamination and degradation of the silicon foundation structure is accelerated by the presence of hydrogen, which is often used as a gas in the environment in which the spectral purity filter is used in order to suppress debris (e.g. debris, such as particles or the like), from entering or leaving certain parts of the lithographic apparatus. Thus, the spectral purity filter may be used as a pellicle, and vice versa. Therefore, reference in the present application to a ‘pellicle’ is also reference to a ‘spectral purity filter’. Although reference is primarily made to pellicles in the present application, all of the features could equally be applied to spectral purity filters.

The present invention has been devised in an attempt to address at least some of the problems identified above.

### SUMMARY OF THE INVENTION

According to a first aspect of the present invention, there is provided a pellicle membrane comprising a population of metal silicide crystals in a silicon-based matrix, wherein the pellicle membrane has an emissivity of 0.3 or more. The silicon-based matrix may include silicon crystals.

The emissivity of a pellicle membrane is related to the temperature at which it operates within a lithographic apparatus. It is desirable for the pellicle membrane to operate at lower temperatures and so higher emissivity is desired. Alternatively or additionally, a higher emissivity also allows a lithographic apparatus to operate at a higher source power since the pellicle membrane will still be able to operate at a suitable temperature despite the increased source power due to the increased emissivity of the pellicle membrane.

The emissivity may be 0.33 or higher, 0.35 or higher, 0.37 or higher, or 0.4 or higher.

The pellicle membrane may have a transmissivity of 90% or more, 91% or more, 92% or more, 93% or more, 94% or more, or 95% or more. Since the pellicle membrane does not include or only includes low levels of atoms which absorb EUV radiation, the transmissivity of the pellicle membrane can be high. Due to the emissivity of the pellicle membrane, the operating temperature of the membrane can be low and/or the pellicle can be used at higher source powers. Generally, an increase in transmissivity leads to a decrease in emissivity, and vice versa. The present invention provides good transmissivity with good emissivity.

The pellicle membrane may include nitrogen in an amount up to around 5 atomic %. The nitrogen may be present in an amount of up to around 4 atomic %, up to around 3 atomic %, up to around 2 atomic %, or up to about 1 atomic %.

It has been found that even low concentrations of nitrogen, such as less than or equal to 5 atomic %, lead to lower resistivity (higher emissivity). In turn, this leads to lower operating temperatures within a lithographic apparatus at the same source power or allows the use of higher source powers.

The metal silicide crystals and/or silicon crystals may have a diameter of 30 nm or less.

The diameter of the crystals can be determined through scanning electron microscope imagery. The diameter may be measured as the largest dimension of an individual crystal. The metal silicide crystals may have a diameter of 28 nm or less, or 25 nm or less. Preferably greater than 90%, greater than 95%, greater than 98%, or greater than 99% of the metal silicide crystals and/or silicon crystals have a diameter of 30 nm or less, of 28 nm or less, or 25 nm or less.

Pellicle membranes comprising metal silicide crystals in a silicon-based matrix typically have a lower emissivity than pellicle membranes comprising molybdenum silicide nitride. Although pellicle membranes comprising metal silicide crystals in a silicon-based matrix typically have greater transmissivity than pellicle membranes comprising molybdenum silicide nitride, this greater transmissivity does not compensate for the decreased emissivity in regards to operating temperature. As such, at the same source power, pellicle membranes comprising metal silicide crystals in a silicon-based matrix have a higher operating temperature. This is disadvantageous since higher temperatures are associated with faster chemical reactions and therefore faster degradation. It is believed that this is due to the low-emissive silicon crystals or amorphous silicon which separate the more highly emissive metal silicide crystals. In addition, compared to a molybdenum silicide nitride composite pellicle, where the distance between molybdenum silicide crystals in a molybdenum silicide nitride composite is less than 10 nm, in a pellicle membrane comprising metal silicide crystals in a silicon matrix, the distance between molybdenum silicide crystals is greater, and additionally the metal silicide crystals are themselves larger. As such, it has been found that decreasing the crystal size provides for improved emissivity without the need to change the chemical composition of the pellicle membrane. As such, the present invention provides for a pellicle membrane with improved emissivity without necessarily changing the chemical composition of the pellicle membrane. This is achieved by influencing the crystals structure of the pellicle membrane in such a way that smaller and more intermixed grains are formed in the final pellicle, which in turn provides improved emissivity.

The metal silicide crystals and/or the silicon crystals may be aligned substantially perpendicular to a surface of the pellicle membrane.

The size of the crystals within the membrane is important with regards to emissivity. The dimensionality of the membrane can therefore be exploited to make smaller crystals. Pellicle membranes are thin, such as 40 nm or less, 30 nm or less, 20 nm or less, 15 nm or less, or 12 nm or less. As such, by providing the crystals perpendicular to the surface, it is possible to limit crystals size and to provide multiple parallel crystal “pillars”. This serves to improve the emissivity of the membrane.

At least some of the population of metal silicide crystals and/or silicon crystals may span the thickness of the membrane. As such, the length of the crystals may be the same as the thickness of the pellicle membrane.

The pellicle membrane may be a multi-layer membrane. A multi-layer membrane is one in which there are stacked layers having different chemical or physical properties. The pellicle membrane may include a layer comprising a population of metal silicide crystals in a silicon-based matrix, which optionally comprises silicon crystals, disposed between one or more layers comprising a silicon molybdenum alloy.

The metal silicide crystals may be molybdenum silicide crystals. Molybdenum silicide is suitable for use in a lithographic apparatus and has high emissivity to result in a lower operating temperature at a given source power and/or the ability to withstand a higher source power.

The silicon matrix may comprise p-Si or SiN. p-Si is used in pellicle membranes for lithographic apparatuses as it is well understood and has high emissivity for EUV radiation.

The silicon-based matrix may be doped. The silicon-based matrix has low emissivity and so may be doped in order to increase its emissivity. The silicon-based matrix may be doped with one or more of boron, phosphorus, and yttrium. The metal silicide, preferably molybdenum silicide crystals, are separated from one another by non-conducting silicon crystals, which limits the emissivity of the pellicle membrane as a whole. Doping increases the electrical conductivity of the silicon crystals and therefore increases emissivity. In addition, it has been found that pellicle membranes comprising a silicon-based matrix rather than a silicon nitride matrix have lower strength. Without wishing to be bound by scientific theory, one reason for this is thought to be due to the greater resistance to HF etching of the silicon nitride matrix. Doping increases the etch resistance of the membrane, thereby limiting the negative effects on the strength of the membrane by inadvertent overetching.

The boron, phosphorus, and/or yttrium dopant may be present in a concentration in the order of 10¹⁵ cm⁻³ to 10²¹ cm⁻³. Pure p-Si membranes can increase in strength from 2.7 GPa to 3.7 GPa by doping the silicon with boron at a concentration of around 10²¹ cm⁻³. As such, doping the present pellicle membranes allows an increase in mechanical strength. Similarly, boron doping increases the emissivity of pure p-Si from 0.02 to 0.06, so the overall emissivity of the membrane is increased.

The pellicle membrane may include from about 10 atomic % to about 30 atomic % molybdenum, optionally from about 15 atomic % molybdenum to about 25 atomic % molybdenum, optionally about 20 atomic % molybdenum.

The pellicle membrane may include from about 90 atomic % to about 70 atomic % silicon, optionally from about 90 atomic % to about 65 atomic %, optionally from about 85 atomic % to about 70 atomic % silicon, optionally about 75 atomic % silicon.

As such, the pellicle membrane may comprise from about 10 atomic % to about 30 atomic % molybdenum, from about 90 atomic % to about 65 atomic % silicon, and about 0-5 atomic % nitrogen. It will be appreciated that small amounts of non-functional impurities may be present. In addition, dopants in the concentrations mentioned herein may be provided.

The thickness of the membrane may be from around 10 nm to around 100 nm. The thickness of the membrane may be around 12 nm, around 15 nm, around 20 nm, around 25 nm, around 30 nm, around 40 nm, around 50 nm, around 60 nm, around 70 nm, around 80 nm, or around 90 nm.

According to a second aspect of the present invention, there is provided a method of manufacturing a pellicle membrane. The method may include at least one step selected from: a) quenching a membrane by removing the membrane from an annealing furnace operating at an annealing temperature and exposing the membrane to ambient temperature so as to rapidly cool the membrane, b) annealing the membrane for a period of less than an hour, c) bombarding the membrane with ions during deposition of the membrane, d) providing a capping layer on the membrane prior to annealing, e) putting a membrane at a temperature of around 500° C. or higher onto a surface at a temperature of around 100° C. or lower so as to induce crystallisation; or f) heating one side of an amorphous membrane to just over the glass transition temperature so as to induce crystallization from the opposite side of the amorphous membrane.

The membrane may comprise a population of metal silicide crystals in a silicon matrix, optionally comprising silicon crystals. The membrane may be a membrane according to the first aspect of the present invention. As such, the method may include providing a membrane comprising a population of metal silicide crystals in a silicon matrix, optionally comprising silicon crystals. Alternatively, the method may include providing a membrane comprising amorphous metal silicide zones in an amorphous silicon matrix. It should be understood that reference to a membrane in the context of the second aspect of the present invention also include reference to a membrane which is at least partially amorphous and is converted into the crystalline or semi-crystalline membrane which is suitable for use in a lithographic apparatus. The membrane in the context of the second aspect of the present invention may therefore be a progenitor membrane of the final pellicle membrane. The membrane referred to in the second aspect of the present invention is converted to the ultimate pellicle membrane by the method herein described. Once the membrane has been treated according to the methods of the second aspect of the present invention, it is suitable for use in a lithographic apparatus. Since the chemical composition of the membrane is unchanged or effectively unchanged during processing according to the method of the second aspect of the present invention, the composition of the membrane may be any as described in respect of the first aspect of the present invention.

The methods of the second aspect of the present invention provide a pellicle membrane with the desired emissivity of 0.3 or greater. This can be achieved in a number of ways.

Previously, annealing was undertaken at a temperature of around 900° C. for 8 hours, after which the furnace is turned off the wafer remains in the furnace for 1.5 to 2 hours. This long annealing process was intended to prevent any changes to the pellicle membrane during operation and results in the formation of large grains within the membrane. It has been found that rapidly cooling the membrane by removing it from the furnace and allowing it to reach room temperature allows the membrane to retain the microstructure present at 900° C., and avoids the size of the crystals growing. In turn this leads to better emissivity of the membrane without changing the chemical composition.

It has also been found that heating the membrane rapidly, particularly in 30 seconds or less, 25 seconds or less, 20 seconds or less, 15 seconds or less, 10 seconds or less, or 5 seconds or less, up to annealing temperature, for example of around 900° C., and annealing for a period of from 1 minute to 10 minutes, and then allowing the membrane to cool also prevents the grains from growing extensively.

Bombarding the substrate from which the pellicle membrane is formed during deposition, such as with high energy ions, for example of Kr or Ar, can change the nucleation mechanism and the final microstructure of the membrane. This also allows directionality of crystal growth to be controlled.

Providing a capping layer on the membrane prior to annealing can also influence the microstructure of the membrane. For example, capping the membrane with a TEOS layer prior to annealing provides more heterogenous nucleation sites for the grains to start growing

The microstructure can also be controlled by controlling the directional growth of crystals therein. By placing a heated membrane on a colder surface, crystallisation can be induced. Similarly, heating an amorphous sample to just above the glass transition temperature, such as around 5° C., around 10° C., around 15° C., or around 20° C., above the glass transition temperature, over a period of time can initiate crystallisation from the colder bottom surface.

Each of these method can be combined as appropriate, except where they are incompatible or exclude one another, to provide a pellicle membrane with a desired microstructure that provides the membrane with the desired emissivity of 0.3 or more.

The annealing may be conducted for around 30 minutes or less, around 20 minutes or less, around 15 minutes or less, around 10 minutes or less, or around 5 minutes or less.

The annealing may be conducted at an annealing temperature of from about 600° C. to about 900° C., optionally from about 600° C. to about 800° C., optionally from about 650° C. to about 700° C. The annealing is conducted at a temperature of around 750° C. or less, optionally around 700° C. or less, optionally around 650° C. or less, or around 600° C. or less.

The annealing may be conducted for a period of up to 10 hours, up to 9 hours, up to 8 hours, or from around 1 hour to around 8 hours.

The method may include a step of doping the pellicle membrane, optionally wherein the dopant is one or more of boron, phosphorus, and yttrium. The dopant may be present in a concentration in the order of 10¹⁵ cm⁻³ to 10²¹ cm⁻³.

According to a third aspect of the present invention, there is provide a pellicle assembly comprising a pellicle membrane according to the first aspect of the present invention or manufactured according to the method of the second aspect of the present invention.

According to a fourth aspect of the present invention, there is provided a lithographic apparatus comprising a pellicle membrane according to the first aspect of the present invention or a pellicle assembly according to the third aspect of the present invention.

According to a fifth aspect of the present invention, there is provided the use of a pellicle membrane, pellicle assembly, lithographic apparatus, or method according to any of the first to fourth aspects of the present invention in a lithographic apparatus or method.

It will be appreciated that features described in respect of one embodiment may be combined with any features described in respect of another embodiment and all such combinations are expressly considered and disclosed herein.

### BRIEF DESCRIPTION OF THE DRAWINGS

Embodiments of the invention will now be described, by way of example only, with reference to the accompanying schematic drawing in which corresponding reference symbols indicate corresponding parts, and in which:

FIG. 1 depicts a lithographic apparatus according to an embodiment of the invention;

FIG. 2 is an SEM image of a broken membrane according to the first aspect of the present invention showing the phase separation between the silicon and molybdenum disilicide crystals;

FIG. 3 is an array of SEM images showing the microstructure of membranes of different thicknesses and prepared under different annealing temperatures; and

FIG. 4 is a graph comparing the operating temperature versus EUV transmissivity operating at 600 w.

The features and advantages of the present invention will become more apparent from the detailed description set forth below when taken in conjunction with the drawings, in which like reference characters identify corresponding elements throughout. In the drawings, like reference numbers generally indicate identical, functionally similar, and/or structurally similar elements.

### DETAILED DESCRIPTION

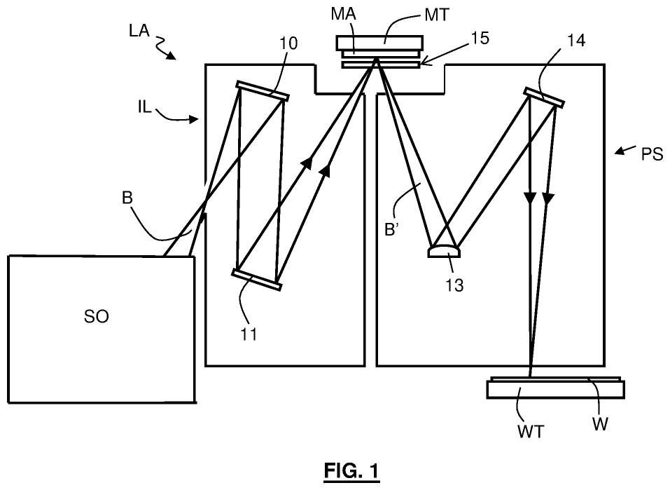

FIG. 1 shows a lithographic system including a pellicle 15 (also referred to as a membrane assembly) according to the present invention. The lithographic system comprises a radiation source SO and a lithographic apparatus LA. The radiation source SO is configured to generate an extreme ultraviolet (EUV) radiation beam B. The lithographic apparatus LA comprises an illumination system IL, a support structure MT configured to support a patterning device MA (e.g. a mask), a projection system PS and a substrate table WT configured to support a substrate W. The illumination system IL is configured to condition the radiation beam B before it is incident upon the patterning device MA. The projection system is configured to project the radiation beam B (now patterned by the mask MA) onto the substrate W. The substrate W may include previously formed patterns. Where this is the case, the lithographic apparatus aligns the patterned radiation beam B with a pattern previously formed on the substrate W. In this embodiment, the pellicle 15 is depicted in the path of the radiation and protecting the patterning device MA. It will be appreciated that the pellicle 15 may be located in any required position and may be used to protect any of the mirrors in the lithographic apparatus.

The radiation source SO, illumination system IL, and projection system PS may all be constructed and arranged such that they can be isolated from the external environment. A gas at a pressure below atmospheric pressure (e.g. hydrogen) may be provided in the radiation source SO. A vacuum may be provided in illumination system IL and/or the projection system PS. A small amount of gas (e.g. hydrogen) at a pressure well below atmospheric pressure may be provided in the illumination system IL and/or the projection system PS.

The radiation source SO shown in FIG. 1 is of a type which may be referred to as a laser produced plasma (LPP) source. A laser, which may for example be a CO₂ laser, is arranged to deposit energy via a laser beam into a fuel, such as tin (Sn) which is provided from a fuel emitter. Although tin is referred to in the following description, any suitable fuel may be used. The fuel may for example be in liquid form, and may for example be a metal or alloy. The fuel emitter may comprise a nozzle configured to direct tin, e.g. in the form of droplets, along a trajectory towards a plasma formation region. The laser beam is incident upon the tin at the plasma formation region. The deposition of laser energy into the tin creates a plasma at the plasma formation region. Radiation, including EUV radiation, is emitted from the plasma during de-excitation and recombination of ions of the plasma.

The EUV radiation is collected and focused by a near normal incidence radiation collector (sometimes referred to more generally as a normal incidence radiation collector). The collector may have a multilayer structure which is arranged to reflect EUV radiation (e.g. EUV radiation having a desired wavelength such as 13.5 nm). The collector may have an elliptical configuration, having two ellipse focal points. A first focal point may be at the plasma formation region, and a second focal point may be at an intermediate focus, as discussed below.

The laser may be separated from the radiation source SO. Where this is the case, the laser beam may be passed from the laser to the radiation source SO with the aid of a beam delivery system (not shown) comprising, for example, suitable directing mirrors and/or a beam expander, and/or other optics. The laser and the radiation source SO may together be considered to be a radiation system.

Radiation that is reflected by the collector forms a radiation beam B. The radiation beam B is focused at a point to form an image of the plasma formation region, which acts as a virtual radiation source for the illumination system IL. The point at which the radiation beam B is focused may be referred to as the intermediate focus. The radiation source SO is arranged such that the intermediate focus is located at or near to an opening in an enclosing structure of the radiation source.

The radiation beam B passes from the radiation source SO into the illumination system IL, which is configured to condition the radiation beam. The illumination system IL may include a facetted field mirror device 10 and a facetted pupil mirror device 11. The faceted field mirror device 10 and faceted pupil mirror device 11 together provide the radiation beam B with a desired cross-sectional shape and a desired angular distribution. The radiation beam B passes from the illumination system IL and is incident upon the patterning device MA held by the support structure MT. The patterning device MA reflects and patterns the radiation beam B. The illumination system IL may include other mirrors or devices in addition to or instead of the faceted field mirror device 10 and faceted pupil mirror device 11.

Following reflection from the patterning device MA the patterned radiation beam B enters the projection system PS. The projection system comprises a plurality of mirrors 13, 14 which are configured to project the radiation beam B onto a substrate W held by the substrate table WT. The projection system PS may apply a reduction factor to the radiation beam, forming an image with features that are smaller than corresponding features on the patterning device MA. A reduction factor of 4 may for example be applied. Although the projection system PS has two mirrors 13, 14 in FIG. 1, the projection system may include any number of mirrors (e.g. six mirrors).

The radiation sources SO shown in FIG. 1 may include components which are not illustrated. For example, a spectral filter may be provided in the radiation source. The spectral filter may be substantially transmissive for EUV radiation but substantially blocking for other wavelengths of radiation such as infrared radiation.

In an embodiment the membrane assembly 15 is a pellicle for the patterning device MA for EUV lithography. The membrane assembly 15 of the present invention can be used for a dynamic gas lock or for a pellicle or for another purpose. In an embodiment the membrane assembly 15 comprises a membrane formed from the at least one membrane layer having an emissivity of 0.3 or more. In order to ensure maximized EUV transmission and minimized impact on imaging performance it is preferred that the membrane is only supported at the border.

If the patterning device MA is left unprotected, the contamination can require the patterning device MA to be cleaned or discarded. Cleaning the patterning device MA interrupts valuable manufacturing time and discarding the patterning device MA is costly. Replacing the patterning device MA also interrupts valuable manufacturing time.

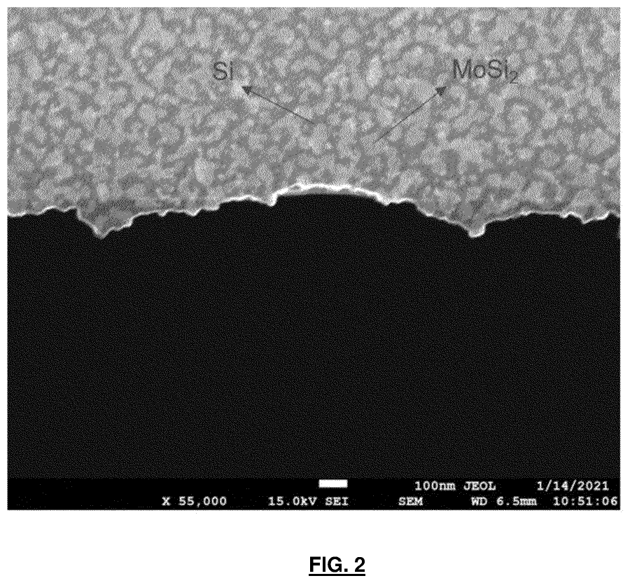

FIG. 2 depicts a scanning electron microscope (SEM) image of a broken pellicle membrane according to a first aspect of the present invention. The silicon crystals and the molybdenum disilicide crystals can be seen. According to the present invention, by controlling the microstructure of the pellicle membrane, it is possible to obtain a pellicle membrane which has good emissivity and high EUV transmissivity. For example, the emissivity may be 0.3 or more. The transmissivity may be 90% or more, or 92% or more. A combination of high emissivity and high EUV transmissivity is desirable when used in an EUV lithography apparatus.

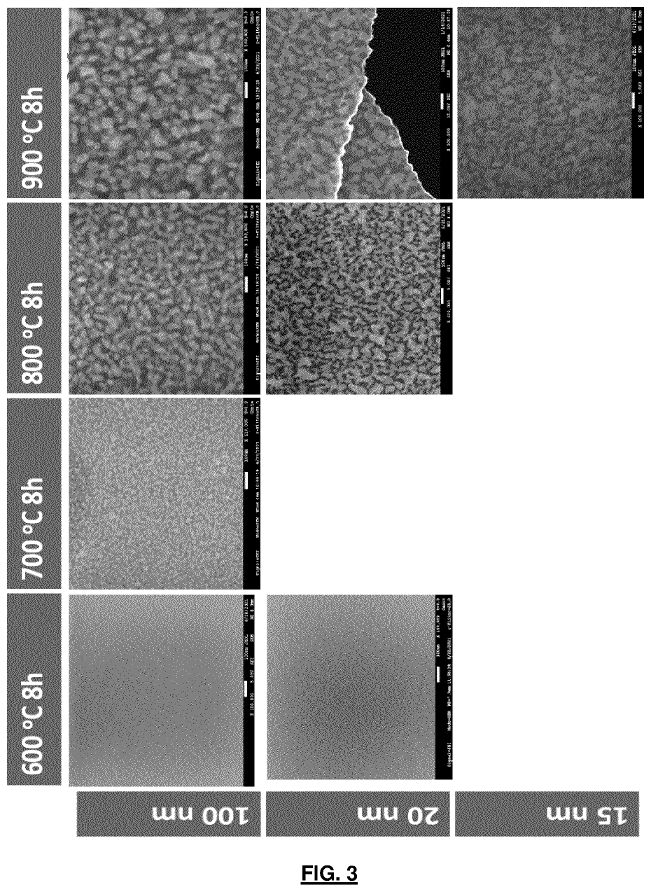

FIG. 3 includes an array of SEM images of different pellicle membranes which have been annealed at different temperatures and which are of different thicknesses. The crystal size increases with annealing temperature. As such, where smaller crystals are desired, a lower annealing temperature may be adopted. All other conditions were held constant and only thickness and duration of annealing were altered.

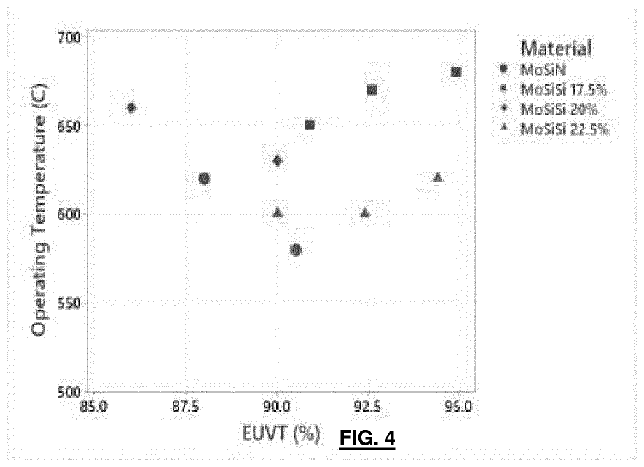

FIG. 4 compares the EUV transmissivity with the operating temperature of three membranes according to the present invention (so-called MoSiSi as they comprise molybdenum silicide in a silicon matrix) versus a molybdenum silicide nitride composite pellicle membrane, which has a much greater amount of nitrogen (up to around 20 atomic %) than even the membranes of the present invention which include nitrogen (up to around 5 atomic %). It can be seen that the membranes of the present invention have higher EUV transmissivities and still operate at similar temperatures. Reference to 17.5%, 20%, and 22.5% refers to the atomic percentage of molybdenum in the various samples.

As such, the present invention provides for pellicle membranes which have similar or better transmissivity as compared to other pellicle membranes, but which have emissivity of at least 0.3 which allows them to operate within lithographic apparatuses, particularly EUV apparatuses. The methods described herein provide multiple ways in which such membranes can be formed.

While specific embodiments of the invention have been described above, it will be appreciated that the invention may be practiced otherwise than as described.

The descriptions above are intended to be illustrative, not limiting. Thus it will be apparent to one skilled in the art that modifications may be made to the invention as described without departing from the scope of the claims set out below.

1. A pellicle membrane comprising a population of metal silicide crystals in a silicon-based matrix, wherein the pellicle membrane has an emissivity of 0.3 or more.

2. The pellicle membrane according to claim 1, wherein the pellicle membrane has a transmissivity of 90% or more.

3. The pellicle membrane according to claim 1, wherein the pellicle membrane includes nitrogen in an amount up to around 5 atomic %.

4. The pellicle membrane according to claim 1, wherein the metal silicide crystals have a diameter of 30 nm or less and/or the silicon-based matrix includes silicon crystals having a diameter of 30 nm or less.

5. The pellicle membrane of claim 1, wherein the metal silicide crystals are aligned substantially perpendicular to a surface of the pellicle membrane, and/or the silicon-based-matrix includes silicon crystals aligned substantially perpendicular to a surface of the pellicle membrane.

6. The pellicle membrane according to claim 1, wherein at least some of the population of metal silicide crystals span the thickness of the membrane, and/or the silicon-based matrix includes silicon crystals which span the thickness of the membrane.

7. The pellicle membrane of claim 1, wherein the pellicle membrane is a multi-layer membrane.

8. The pellicle membrane according to claim 7, wherein the pellicle membrane includes a layer comprising the population of metal silicide crystals in a silicon-based matrix between one or more layers comprising a silicon molybdenum alloy.

9. The pellicle membrane according to claim 1, wherein the metal silicide crystals are molybdenum silicide crystals.

10. The pellicle membrane according to claim 1, wherein the silicon-based matrix includes p-Si, polySi, or SiN, and/or wherein the silicon-based matrix includes silicon crystals.

11. The pellicle membrane according to claim 1, wherein the silicon-based matrix is doped.

12. The pellicle membrane according to claim 11, wherein the silicon-based matrix is doped with one or more selected from: boron, phosphorus or yttrium, in a concentration in the order of 10¹⁵ cm⁻³ to 10²¹ cm⁻³.

13. The pellicle membrane according to claim 1, wherein the pellicle membrane includes from about 10 atomic % to about 30 atomic % molybdenum.

14. The pellicle membrane according to claim 1, wherein the pellicle membrane includes from about 90 atomic % to about 65 atomic % silicon.

15. The pellicle membrane according to claim 1, wherein the thickness of the pellicle membrane is from about 10 nm to about 100 nm.

16. A method of manufacturing a pellicle, the method including at least one step selected from:
a) quenching a membrane of the pellicle by removing the membrane from an annealing furnace operating at an annealing temperature and exposing the membrane to ambient temperatures so as to rapidly cool the membrane;
b) heating a membrane of the pellicle up to annealing temperature in 30 seconds or less;
c) bombarding a membrane of the pellicle with ions during deposition of the membrane;
d) providing a capping layer on a membrane of the pellicle prior to annealing;
e) putting a membrane of the pellicle at a temperature of around 500° C. or higher onto a surface at a temperature of around 100° C. or lower so as to induce crystallization; or
f) heating one side of an amorphous membrane of the pellicle to just over the glass transition temperature so as to induce crystallization from the opposite side of the amorphous membrane.

17. (canceled)

18. The method according to claim 16, wherein annealing is conducted at an annealing temperature of from about 600° C. to about 900° C.

19. The method according to claim 16, wherein annealing is conducted at a temperature of around 750° C. or less.

20. (canceled)

21. The method according to claim 16, further comprising doping the pellicle membrane, wherein the dopant is one or more selected from: boron, phosphorus, and yttrium.

22. The method according to claim 21, wherein the dopant is present in a concentration in the order of 10¹⁵ cm⁻³ to 10²¹ cm⁻³.

23.-25. (canceled)
